(19) United States
(12) Patent Application Publication
(10) Pub. No.: US 2008/0137296 A1
(43) Pub. Date: Jun. 12, 2008

(54) Active Cooling of Outdoor Enclosure Under Solar Loading

(75) Inventors: Ed DuQuette, Marseilles, IL (US); Minesh Patel, Carol Stream, IL (US); Anthony Walker, Aurora, IL (US); Craig Cors, Aurora, IL (US); Greg Lantz, Batavia, IL (US); Daniel Wynard, Lockport, IL (US)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: WESTELL TECHNOLOGIES, INC., Aurora, IL (US)

(21) Appl. No.: 11/857,282

(22) Filed: Sep. 18, 2007

Related U.S. Application Data
(60) Provisional application No. 60/869,539, filed on Dec. 11, 2006.

(51) Int. Cl. H05K 7/20

(52) U.S. Cl. 361/695

(57) ABSTRACT

An outdoor enclosure for electronic equipment is described. A shroud mounted around the enclosure provides a plenum for external air, as well as protection from solar loading. A fan located inside the equipment enclosure circulates the air inside the equipment enclosure downward along the sides of the enclosure to accomplish heat exchange with external air. Another fan draws external air upwardly across the surfaces of the equipment enclosure. The heated external air is exhausted at the top of the shroud.

### PRIORITY

The present patent application claims priority under 35 U.S.C. §119(e) to U.S. Provisional Patent Application Ser. No. 60/869,593, which was filed Dec. 11, 2006. The full disclosure of U.S. Provisional Patent Application Ser. No. 60/869,593 is incorporated herein by reference.

### FIELD

The present invention relates generally to outdoor enclosures for electrical equipment, and more particularly, to systems and methods for cooling internal air of these enclosures through heat exchange with external air.

### BACKGROUND

Various kinds of electrical equipment, such as telecommunications equipment, are located outdoors in enclosures to protect the electrical components from the outside environment. Because the electrical equipment typically gives off heat in normal operation, heat may need to be removed from the enclosure in order to maintain acceptable operating temperatures for the equipment. Existing enclosures use methods to cool the inside air of the equipment enclosure using air conditioning systems or heat exchange with external air. Air conditioning systems are complex, expensive, use large amounts of energy, and require more maintenance than heat exchange with external air. Therefore, external air heat exchange with outside air is generally preferred for cooling electrical equipment cabinets.

Various outdoor electrical equipment enclosures use heat exchange with outdoor air to cool the interior space of an enclosure containing the electrical components. However, these systems may still use large amounts of energy, redraw air heated by the heat exchange system, and circulate the outside and internal air flows in an inefficient manner. Therefore, there is a need for systems and methods for circulating external air to cool electronic equipment enclosures in a more efficient manner.

### SUMMARY

The present invention relates to a shroud assembly for use with an equipment enclosure for electronic equipment. The present invention provides efficient heat exchange between external air in the shroud assembly and the internal air in the equipment enclosure. A top fan draws external air upwardly across the heat exchange surfaces of the equipment enclosure. These heat exchange surfaces may be any number of the upper, side, or bottom surfaces of the equipment enclosure. Internal fans inside the equipment enclosure circulate the internal air down along the side walls of the equipment enclosure, and then draw the air up through the electronic equipment. The present invention accomplishes efficient heat exchange by directing external air in an upward direction and internal air in a downward direction. In this way the airflow complies with the tendency of warm air to rise and cold air to sink, reducing the load on the internal fan and external air fan.

A further advantage is that the effect of solar heat loading is decreased by locating the external air intake at the opposite end of the equipment enclosure from the external air exhaust, thereby decreasing the possibility of drawing in heated exhausted external air into the heat exchange system.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Presently preferred embodiments are described below in conjunction with the appended drawing figures, wherein like reference numerals refer to like elements in the various figures, and wherein:

FIG. 1 is a view of the equipment enclosure and electronic equipment, according to an example;

FIG. 2 is a cutaway view of the equipment enclosure with airflow directions shown, according to an example;

FIG. 3a is a view of the shroud assembly, according to an example;

FIG. 3b is a view of the inner shroud, according to an example;

FIG. 3c is a view of the outer shroud, according to an example;

FIG. 3d is a view of the shroud, according to an example;

FIG. 4 is an exploded view of the top fan assembly, according to an example;

FIG. 5 is a cutaway view of the equipment enclosure, shroud, and top fan assembly, showing the internal and external airflows when the system is in operation, according to an example;

FIG. 6 is a cutaway view of the equipment enclosure, shroud assembly, and top fan assembly, showing the internal and external airflows when the system is in operation, according to an example;

FIG. 7 is a view of the shroud assembly and the top fan assembly, showing a reflective solar coating applied to the external surfaces of the shroud assembly and the top fan assembly;

FIG. 8 shows a cutaway view of the equipment enclosure with a temperature sensor inside the equipment enclosure, and the internal and top fan controls; and

FIG. 9 shows a temperature sensor connected to a processing means, which is in communication with the internal and top fan controls.

### DETAILED DESCRIPTION

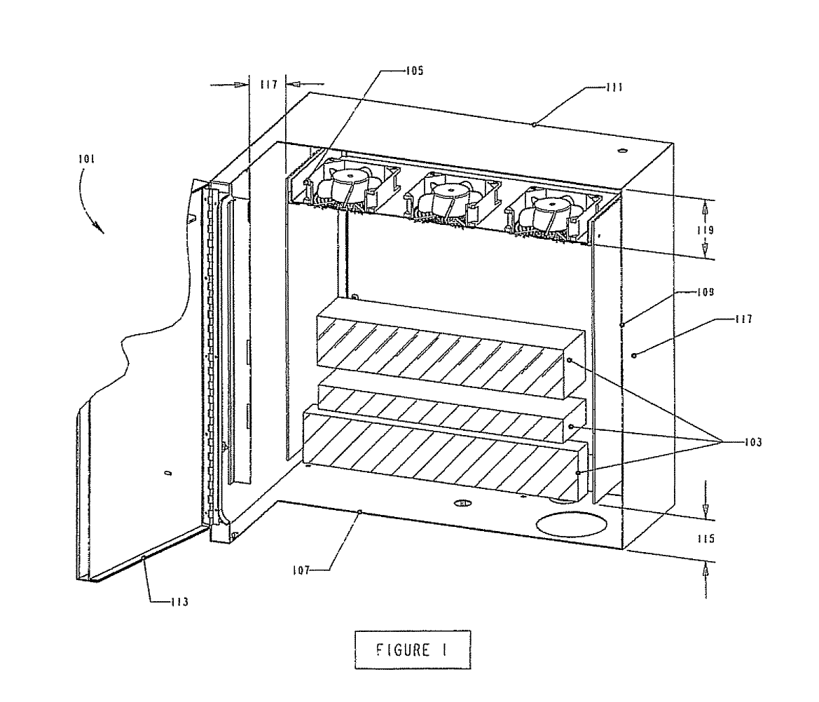

FIG. 1 shows an equipment enclosure 101. The equipment enclosure 101 has a bottom wall 107, an upper wall 111, and four side walls 109. The walls 107, 109, 111 may form a rectangular or square box shape. An equipment enclosure door 113 may be located on any of the side walls 109 to allow access to the inside of the equipment enclosure 101.

The equipment enclosure 101 may also include electronic equipment 103. The electronic equipment 103 may be equipment typically used in telecommunications, security, lighting, signal processing, or any other type of electronic equipment. The electronic equipment 103 is mounted in the equipment enclosure 101 in a manner such that a bottom internal channel 115 exists between the electronic equipment 103 and the bottom wall 107, an upper internal channel 119 exists between the electronic equipment 103 and the upper wall 111, and a side internal channel 117 exists between the electronic equipment 103 and at least two of the side walls 109. Many standard commercial equipment enclosures contain tracks which may be used to mount the electronic equipment 103 in a manner such that the bottom internal channel 115, the side internal channels 117, and the upper internal channel 119 are created between the electronic equipment 103 and the bottom, side and upper walls 107, 109, 111 of the equipment enclosure 101.

The equipment enclosure 101 may include one or more internal fans 105. FIG. 1 depicts three internal fans 105; however, more or fewer than three internal fans 105 may be used. Each of the internal fans 105 may be a linear fan. However, other fan types may be used. The internal fans 105 may be mounted in the upper internal channel 119. The equipment enclosure 101 containing the electronic equipment 103 may be sealed in order to prevent internal air (i.e., air internal to the equipment enclosure 101) from mixing with external air (i.e., air external to the equipment enclosure 101).

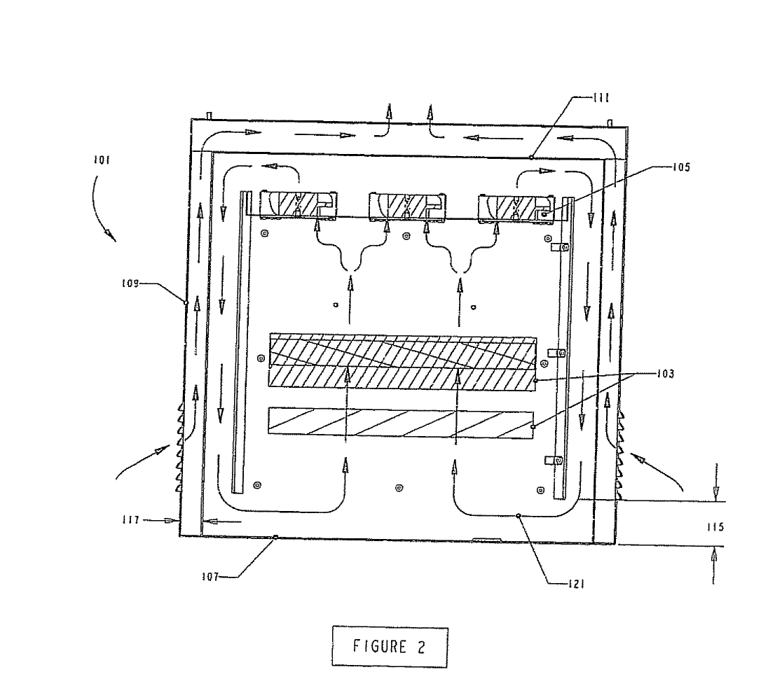

FIG. 2 shows an internal air flow direction 121 of the internal air in the equipment enclosure 101 during operation of the internal fans 105. The internal fans 105 draw the internal air in an upward direction through the electronic equipment 103. The internal fans 105 exhaust the internal air upwardly and the upper wall 111 of the equipment enclosure 101 deflects the internal air. Air pressure from the internal fans 105 drives the internal air down the side internal channels 117. The internal air then enters the bottom internal channel 115 and is drawn up again through the electronic equipment 103 by the internal fan 105. In this way, the internal air removes heat from the electrical equipment 103. The internal air is conversely heated, and is at its highest temperature at the upper wall 111, after being drawn through the electronic equipment 103.

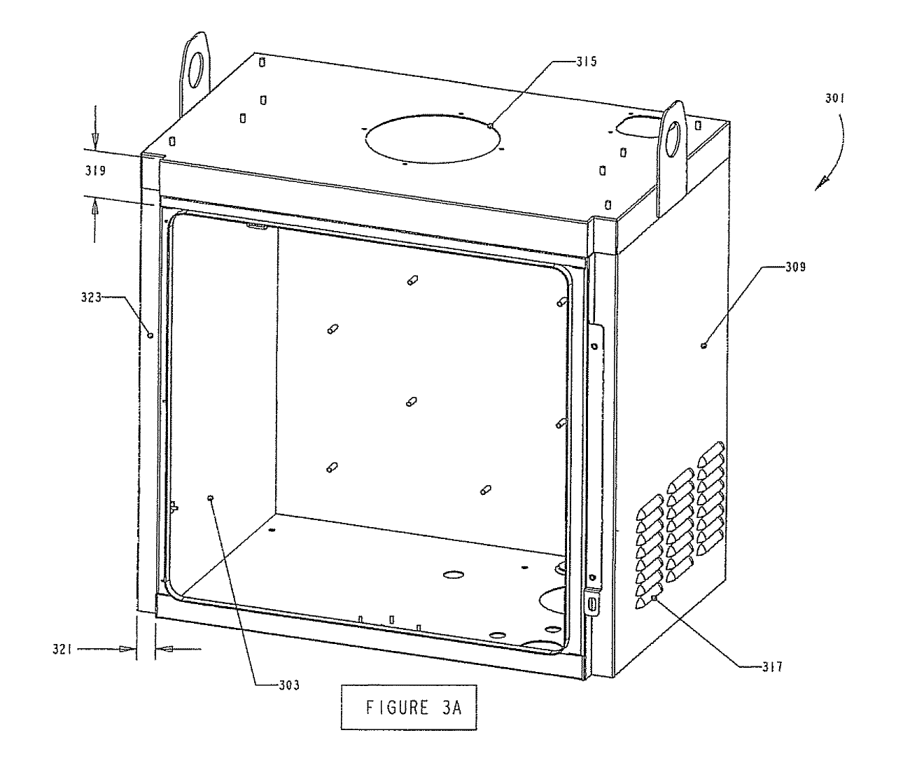

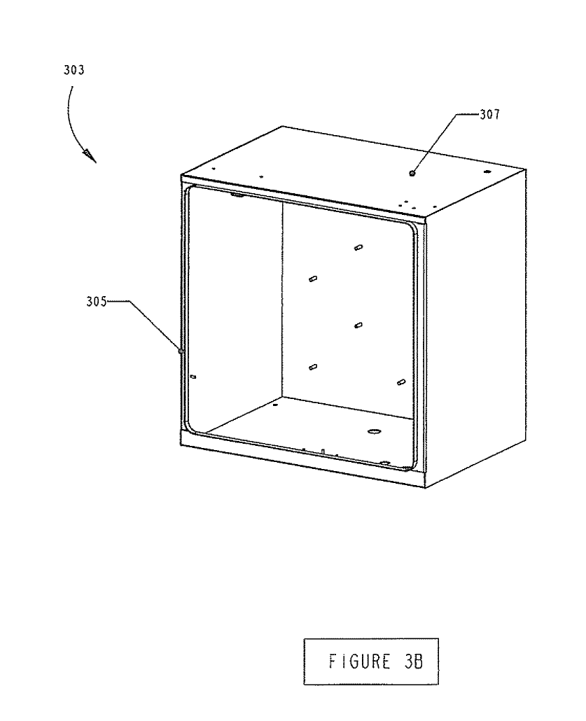

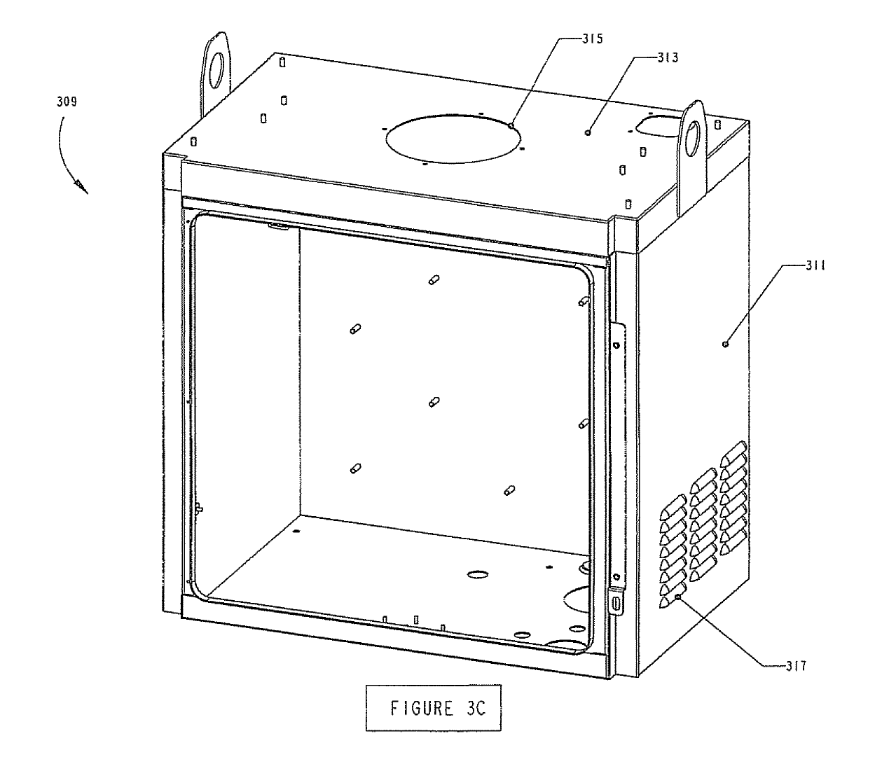

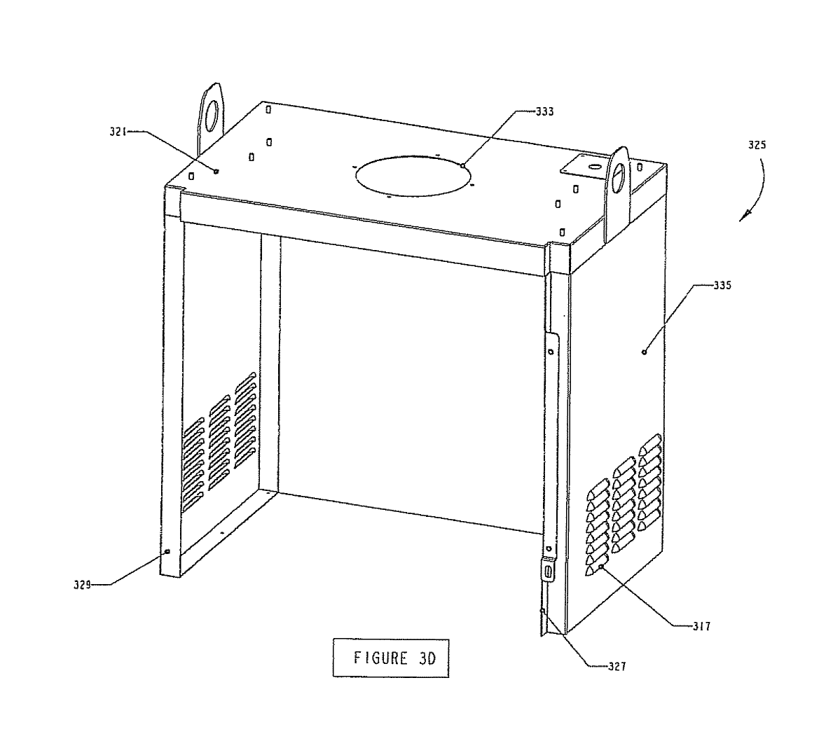

A shroud mounted around the equipment enclosure 101 provides a plenum for heat exchange with the external air, as well as protection from solar heat loading. FIG. 3a shows a shroud assembly 301. The shroud assembly 301 may have an outer shroud 309 and an inner shroud 303. A space located between the outer shroud 309 and the inner shroud 303 forms a shroud upper channel 319 and shroud side channels 321. The shroud side channels 319 may exist on two or three sides of the shroud assembly 301. A shroud front wall 323 joins the outer shroud 309 and the inner shroud 303 along the front face of the shroud assembly 301. The shroud front wall 323 extends between inner shroud side walls 305 and outer shroud side walls 311, and between inner shroud upper wall 307 and outer shroud upper wall 313. See FIGS. 3b and 3c.

FIG. 3b shows the inner shroud 303. The inner shroud 303 has the inner shroud side walls 305 and the inner shroud upper wall 307. The inner shroud upper wall 307 and inner shroud side walls 305 may form a rectangular or square shape, with one side and the bottom portion of the inner shroud 303 left open.

FIG. 3c shows the outer shroud 309. The outer shroud 309 has the outer shroud upper wall 313 and the outer shroud side walls 311. The outer shroud upper wall 311 and the outer shroud side walls 311 may form a rectangular or square shape, with one side and the bottom portion of the outer shroud 309 left open.

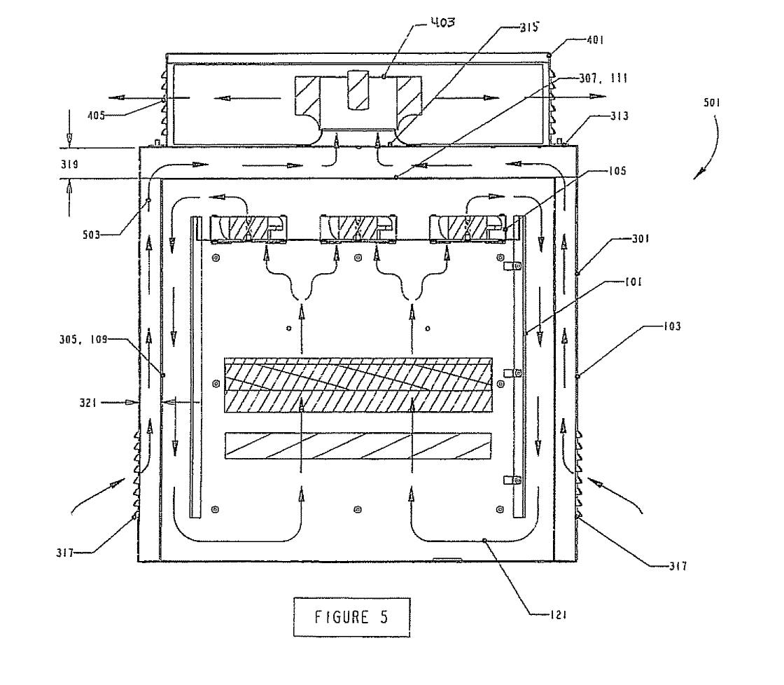

A shroud inlet 317 is located on a lower portion of the shroud side walls 311. The shroud inlet may be a variety of shapes. For example, the shape and size of the shroud inlet 317 may be chosen based on the size of the shroud or the parameters of the top fan assembly, as described with reference to FIG. 5.

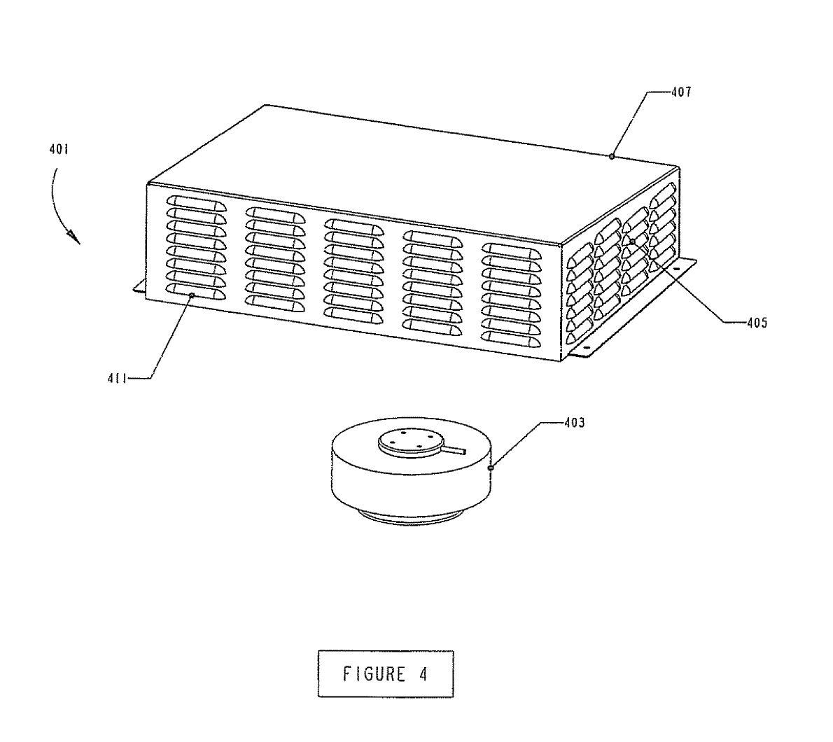

A shroud outlet 315 is located in the outer shroud upper wall 313. The shroud outlet 315 may be a variety of shapes. For example, the shape of the shroud outlet 315 may be chosen based on the parameters of a top fan assembly mounted on the shroud outlet 315, described with reference to FIGS. 4.

FIG. 3d shows an alternative embodiment for the shroud assembly 301: a single-walled shroud assembly 325. The shroud assembly 325 has shroud upper wall 331, shroud side walls 335, and a shroud front wall 329. The shroud upper wall 331 and the shroud side walls 335 may form a rectangular or square shape, with one side and the bottom portion of the shroud assembly 325 left open.

A shroud inlet 317 is located on a lower portion of the shroud side walls 311. The shroud inlet may be a variety of shapes. For example, the shape and size of the shroud inlet 317 may be chosen based on the size of the shroud or the parameters of the top fan assembly, as described with reference to FIG. 5.

A shroud outlet 333 is located in the shroud upper wall 331. The shroud outlet 333 may be a variety of shapes. For example, the shape of the shroud outlet 333 may be chosen based on the parameters of a top fan assembly mounted on the shroud outlet 333, described with reference to FIG. 4. The shroud front wall 329 is located along the shroud upper wall 331 and the shroud side walls 335 on the front face of the shroud assembly 325 that is left open.

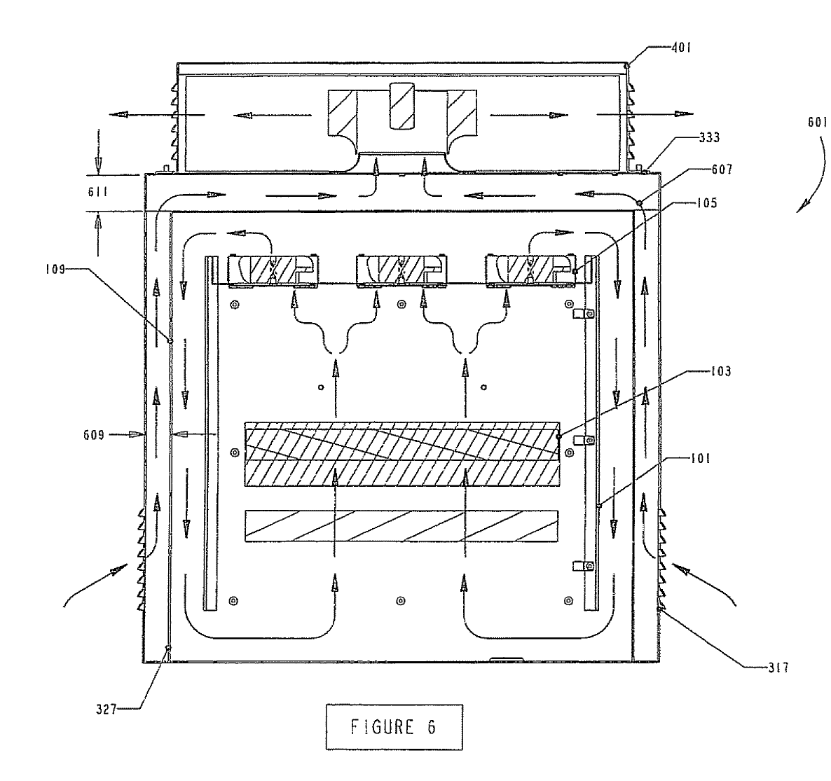

The shroud assembly 325 may have a seal 327 located along the inside surface of the shroud front wall 329. The seal 327 may decrease the pressure drop caused by air leakage between the shroud front wall 329 and the equipment enclosure 101 when the two are assembled. The seal 327 may be a silicone or polyurethane, or any other commonly-known sealant, or may be a gasket composed of rubber, silicone, plastic polymer or any other type of commonly-known gasket. Additionally, the seal 327 may be installed onto the shroud assembly 325 before or after it is fitted over the electronic enclosure 101 as described with respect to FIG. 6.

FIG. 4 shows an exploded view of a top fan assembly 401. The top fan assembly 401 is located on top of the shroud assemblies 301, 325. The top fan assembly 401 has a top fan 403, a top fan housing 407, and a top fan exhaust 405. The top fan housing 407 has four top fan housing side walls 411 and a top fan housing roof 409. The top fan housing 407 may have a rectangular or square shape. One or more of the top fan housing side walls 411 may have top fan exhausts 405 through which external air may be exhausted from the shroud assemblies 301, 325 by the top fan 403. The top fan housing roof 409 covers the top area of the top fan housing 407. The top fan 403 is located inside the top fan housing 407. The top fan 403 may be a centrifugal fan. However, other fan types may be used. The top fan 403 exhausts air laterally through the top fan exhausts 405 of the top fan housing 407.

FIG. 5 shows a cooling system 501. The cooling system 501 has the equipment enclosure 101, the shroud assembly 301, and the top fan assembly 401. The shroud assembly 301 fits over the equipment enclosure 101 so that the inner shroud side walls 305 contact the side walls 109 and the upper wall 111 of the equipment enclosure 101. The top fan assembly 401 is located on top of the shroud assembly 301 and is positioned so that the top fan 403 may draw external air through the shroud outlet 315.

The top fan 403 draws external air through the shroud inlet 317, up through the shroud side channels 321, and into the shroud upper channel 319. The external air is then drawn up through the shroud outlet 315, and the top fan 403 then exhausts the external air laterally through top fan exhausts 405. By drawing the external air up through the shroud side channels 321, a laminar airflow may be achieved. Laminar airflow results in decreased airflow resistance and pressure drop across the top fan 403 and, therefore, decreased work and energy requirements for the top fan 403.

When the cooling system 501 is in operation, heat from the equipment enclosure 101 is transferred by the internal air to the side walls 109 and the upper wall 111 of the equipment enclosure 101. The side walls 109 and the upper wall 111 then transfer the heat in the side walls 109 and the upper wall 111 to the inner shroud side walls 305 and the inner shroud upper wall 307. The heat in the inner shroud side walls 305 and the inner shroud upper wall 307 is then transferred to the external air in the shroud side channel 321 and the shroud upper channel 319.

As the internal air is pushed along the upper wall 111 and down the side walls 109 of the equipment enclosure 101, the internal air is cooled by transferring heat through the side walls 109 with external air contained in the shroud upper channel 319 and the shroud side channels 321. Conversely, as the external air is drawn up through the shroud side channel 319 and across the side walls 109 of the equipment enclosure 101, the external air draws heat across the side walls 109 from the internal air, thereby, cooling the internal air and heating the external air. This heat exchange continues along the length of the side walls 109 and the upper wall 111 of the equipment enclosure 101. Thus, the external air is at its highest temperature when drawn through the top fan 315 and exhausted from the top fan exhaust 411. The internal air is at its lowest temperature in the bottom internal channel 115 of the equipment enclosure 101 at the point where drawn across the electronic equipment 103.

This embodiment may provide advantages because the dimensions of the shroud upper channel 319, the shroud side channels 321 and the shroud inlet 317 are known so that the power requirements of the top fan 403 may be more accurately determined. Also, because the shroud assembly 501 has an inner shroud 303, an outer shroud 309 and the shroud front wall 323, there is less pressure loss from air leakage then when a seal is used as described with respect to FIG. 6. Therefore, the top fan 403 may consume less power because there is less air leakage for the shroud assembly 501.

FIG. 6 shows a cooling system 601. The cooling system 601 has the shroud assembly 325, the equipment enclosure 101, and the top fan assembly 401. The shroud assembly 325 is fastened to the equipment enclosure 101 so as to leave a space between the side walls 109 and the upper wall 111 of the equipment enclosure 101 and the shroud assembly 325. The space between the shroud assembly 325 and the upper wall 111 forms the shroud upper channel 611. The space between the shroud assembly 325 and the side walls 109 forms the shroud side channel 609. The shroud side channels 609 may exist on two or three sides of the shroud assembly 325.

The top fan assembly 401 is located on top of the shroud assembly 325 and may be secured to the shroud assembly 325. The top fan assembly 401 is secured to the shroud assembly 325 so that the top fan 403 may draw external air through the shroud outlet 333. The shroud front wall 329 may be sized to fit the equipment enclosure 101. The seal 327 around the shroud front wall 329 provides a seal between the shroud front wall 329 and the equipment enclosure 101.

The top fan 403 draws external air through the shroud inlet 317, up through the shroud side channels 609, and into the shroud upper channel 611. The external air is then drawn up through the shroud outlet 333, and the top fan 403 then exhausts the external air laterally through top fan exhausts 405. By drawing the external air up through the shroud side channels 609, a laminar flow may be achieved. Laminar airflow results in decreased airflow resistance and pressure drop across the top fan 403, and therefore decreased work and energy requirements for the top fan 403.

As the internal air is pushed along the upper wall 111 and down the side walls 109 of the equipment enclosure 101, the internal air is cooled by transferring heat through the side walls 109 with external air contained in the shroud upper channel 611 and the shroud side channels 609. Conversely, as the external air is drawn up through the shroud side channel 609 and across the side walls 109 of the equipment enclosure 101, the external air draws heat across the side walls 109 from the internal air, thereby, cooling the internal air and heating the external air. This heat exchange continues along the length of the side walls 109 and the upper wall 111 of the equipment enclosure 101. Thus, the external air is at its highest temperature when drawn through the top fan 403 and exhausted from the top fan exhaust 405, and the internal air is at its lowest temperature in the bottom internal channel 115 of the equipment enclosure 101 where drawn across the electronic equipment 103.

The cooling system 601 may provide the advantage that a standard-size shroud assembly 325 may be used for a number of different sizes of equipment enclosures 101. Additionally, heat exchange is made more efficient because the heat from the equipment enclosure 101 need only pass through the walls 107, 109, 111 of the equipment enclosure 101 to be transferred to the external air in the channels of the shroud 609, 611.

Many types of materials are suitable for the surfaces across which heat exchange takes place, such as the side walls 109 and the upper wall 111 of the equipment enclosure 101, and the inner shroud side walls 305 and the inner shroud upper wall 307 of the shroud assembly 301. A material which is highly conductive, such as aluminum 50/52H32, is suitable to facilitate heat exchange across the side walls 109 and the upper wall 111 of the equipment enclosure 101. However, any highly conductive material may be used. Additionally, coating the conductive material with a powder-coat paint having a low emissivity and a high reflectivity value will prevent additional heat from being emitted into the equipment enclosure 101. The powder-coat paint further increases the heat exchange efficiency of the cooling systems 501, 601.

The cooling systems 501, 601 result in increased efficiency. As the external air draws heat from the equipment enclosure 101, the external air is warmed and, thus, the air pressure increases. The increased air pressure causes the heated external air to rise relative to the cooler external air being drawn into the shroud inlets 317 by the top fan 403. The natural tendency of the wanner external air to rise relative to the cooler external air reduces the energy requirements of the top fan 403. Similarly, as the internal air is pushed down across the side walls 109 of the equipment enclosure 101, the internal air is cooled and, thus, decreases in pressure. The natural tendency of the cooled internal air to sink relative to the wanner internal air located at the upper wall 111 of the equipment enclosure 101 also decreases the energy load of the internal fans 105.

The cooling systems 501, 601 also result in increased efficiency because the cooling systems 501, 601 avoid drawing into the shroud inlets 317 the warmed air exhausted from the top fan exhaust 405. The problem of redrawing exhausted heated external air into the shroud inlets 317 is avoided by locating the shroud inlets 317 on the lower portion of the shroud side walls 311, 335 and exhausting the heated external air at top of the top fan assembly 401 on the opposite end of the cooling systems 501, 601 from the shroud inlets 317. Avoiding this problem increases efficiency because air exhausted from the top fan exhaust 405 may be wanner than the ambient temperature.

Also, the cooling systems 501, 601 reduce the effect of solar heat loading by locating the shroud inlets 317 on the lower portion of the shroud side walls 311, 335. Solar heat loading may increase the surface temperature of the shroud assemblies 301, 325 and, thus, may raise the temperature of the air close to the surfaces of the shroud assemblies 301, 325 as well. By locating the shroud inlets 317 on the lower portion of the shroud side walls 311, 335, and away from any surfaces that may be exposed to solar heat loading, the cooling systems 501, 601 are able to draw cooler external air. Drawing cooler external air may increase the amount of heat transferred from the internal air to the external air and, thus, reduces the energy requirements of the top fan 403.

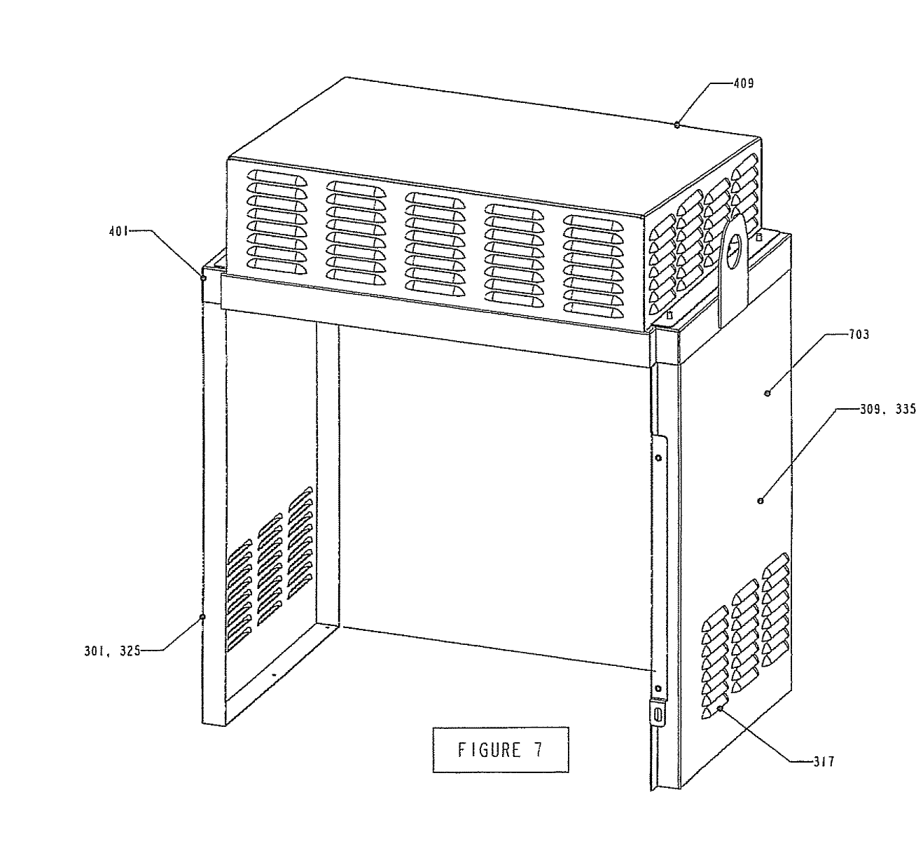

FIG. 7 shows the shroud assemblies 301, 325 with the top fan assembly 401. Any or all of the exterior surfaces of the shroud assemblies 301, 325 may have a reflective coating 703 that deflects a portion of the radiant heat transmitted by solar heat loading. The reflective coating 703 may be any type of solar reflective paint. One example of solar reflective paint is Lo/MIT I/II made by Solec. The reflective coating 703 may decrease the solar heat loading on the equipment enclosure 101 and, thus, less energy may be required from the fans 105, 403 to cool the electronic equipment 103.

The dimensions of the shroud may be changed based on predictions about the heat loads from the equipment enclosure 101 and solar loading. For example, if the dimensions of an equipment enclosure 101 are reduced and the same amount of electronic equipment 103 was contained therein, the necessary heat transfer rate per square unit of area would be expected to rise. The dimensions of the shroud assembly 301, 325 may change in order to properly fit around the equipment enclosure 101. If the dimensions of the shroud assembly, 301, 325 are changed, the solar heat load element will also change because of the change in surface area of the shroud assembly 301, 325 exposed to sunlight. Further, with a change in the dimensions of the equipment enclosure 101 and the dimensions of the shroud assembly 301, 325, the heat transfer rate will change because of the change in the amount of heat transfer area. The amount of change in heat loading and heat transfer rate may be predicted, and the parameters of the shroud assembly 301, 325 and the top fan 401 may be changed in order to provide sufficient cooling. The size of the shroud side channels 321, 603 and/or the shroud upper channel 319, 611 may be changed in order to obtain sufficient air flow to sufficiently cool the equipment enclosure. Similarly, the parameters of the top fan 401, such as airflow capacity, may be changed based on predicted values for heat loading.

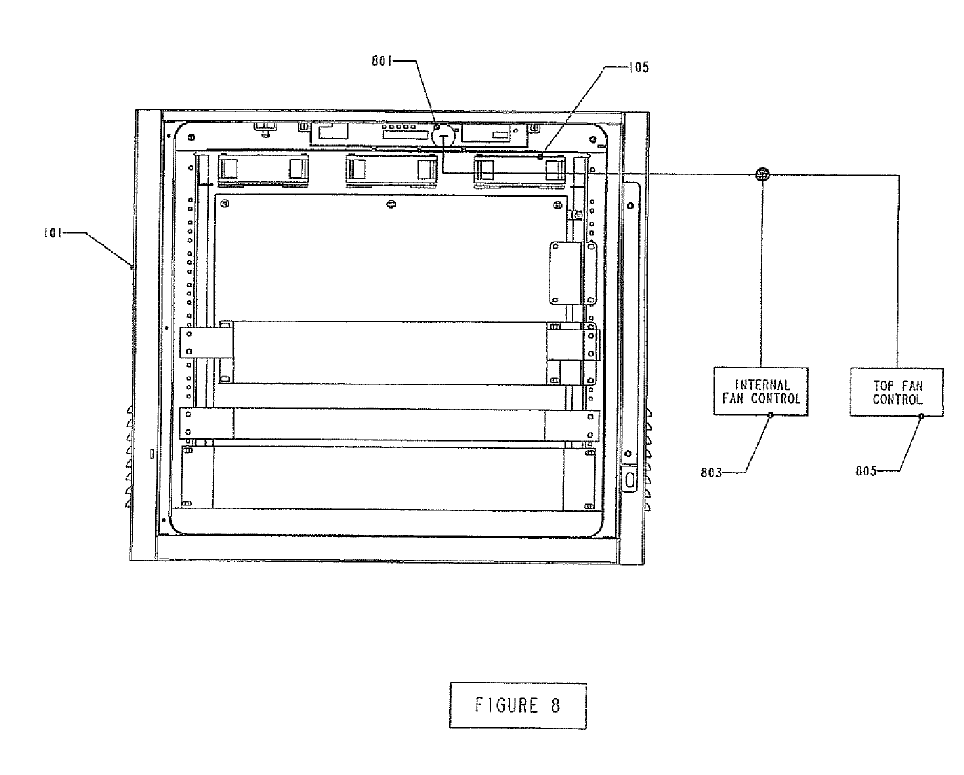

FIG. 8 shows the equipment enclosure 101 containing a temperature sensor 801. The temperature sensor 801 may be located inside the equipment enclosure 101 to obtain the temperature inside the equipment enclosure 101. The temperature measured by the temperature sensor 801 may be used to control the operation of the internal fans 105 and the top fan 403 so as to provide cooling as needed for the electronic equipment 103.

The temperature measured by the temperature sensor 801 is provided to an internal fan control 803 and a top fan control 805. The internal fan control 803 and the top fan control 805 may be a relay or combination of relays. Alternatively, a single relay may act as both the internal fan control 803 and the top fan control 805. Alternatively, the fan controls 803, 805 may be a processor capable of receiving a temperature signal. The internal fan control 803 and the top fan control 805 may also be controls packaged with the top fan 403 and the internal fans 105.

If multiple internal fans 105 are used, the internal fan control 803 may be used to cycle the internal fans 105 on and off to achieve a desirable amount of cooling. Alternatively, if a variable-speed internal fan 105 is selected, the speed of the internal fan 105 may be cycled up or down according to the cooling needs of the electronic equipment 103.

Similarly, the top fan 403 may be a single-speed fan or a variable-speed fan. A single-speed top fan 403 may be cycled on and off by the top fan control 805 according to the cooling needs of the electronic equipment 103. If a variable-speed top fan 403 is selected, the top fan control 805 may cycle the speed of the top fan 403 up or down depending on the cooling needs of the electronic equipment 103. By controlling the internal fans 105 and the top fan 403 to operate as needed to maintain an acceptable operating temperature for the electronic equipment 103, the energy requirements of the internal fans 105 and the top fan 403 may be further reduced.

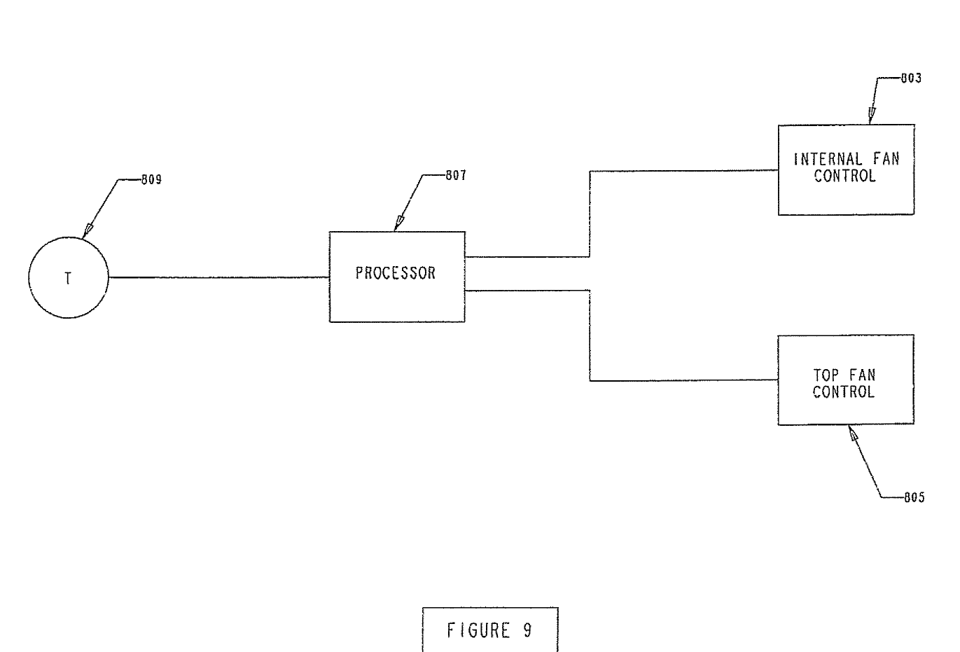

FIG. 9 shows a temperature sensor 809, a processor 807, the internal fan control 803, and the top fan control 805. The temperature sensor 809 may be located inside the equipment enclosure 101. Alternatively, the temperature sensor 809 may be located outside the equipment enclosure 101 to read the external air temperature. An output signal from the temperature sensor 809 may be provided to the processor 807. The processor 807 may be a microprocessor, a controller, an application specific integrated circuit (ASIC) and/or any appropriate combination of software, hardware, and/or firmware.

The processor 807 communicates with the internal fan control 803 and top fan control 805 in order to operate the internal fans 105 and the top fan 403 as needed to maintain an acceptable operating temperature for the electronic equipment 103.

The internal fans 105 and the top fan 403 may be controlled based on the temperature inside the equipment enclosure 101. The internal fans 105 and the top fan 403 may be operated when the temperature inside the equipment enclosure 101 rises above a defined setpoint. For example, the setpoint may be defined as a temperature specified by the manufacturer of the electronic equipment 103 as necessary for proper operation of the electronic equipment 103.

Alternatively, the temperature sensor 809 may be located outside the equipment enclosure 101. Because the external air temperature affects the rate of heat transfer between the internal air and the external air, the speed and/or runtime of the internal fans 105 and the top fan 403 necessary to maintain an acceptable operating temperature for the electronic equipment 103 inside the equipment enclosure 101 may be projected based on the external air temperature.

It should be understood that the illustrated embodiments are examples only and should not be taken as limiting the scope of the present invention. The claims should not be read as limited to the described order or elements unless states to that effect. Therefore, all embodiments that come within the scope and spirit of the following claims and equivalents are claimed as the invention.

We claim:

1. A shroud assembly for cooling electronic equipment, comprising in combination:
an outer shroud having three side walls and an upper wall, wherein the upper wall of the outer shroud has an opening;
an inner shroud having three side walls and an upper wall;
a shroud front wall joining the outer shroud and the inner shroud along an open side of the inner shroud and the outer shroud, wherein at least one channel is located between the outer shroud side walls and the inner shroud side walls; and
a top fan that is mounted on the upper wall of the outer shroud, and wherein the top fan draws external air in an upward direction between the side walls of the inner shroud and the outer shroud.

2. The assembly of claim 1, wherein the top fan draws the external air into the shroud assembly through an inlet located on a lower portion of at least one of the shroud side walls.

3. The assembly of claim 1, wherein at least one external surface of at least one of the top fan and the shroud assembly has a reflective coating.

4. The assembly of claim 1, wherein the shroud assembly is located around an equipment enclosure.

5. The assembly of claim 1, wherein at least one of the side walls and upper wall of the inner shroud is coated with a powder-coat paint.

6. The assembly of claim 4, wherein the equipment enclosure comprises:
electronic equipment;
at least one internal fan, wherein the internal fan directs air inside the equipment enclosure in a downward direction across side walls of the equipment enclosure; and
at least one channel between the electronic equipment and the side walls of the equipment enclosure, wherein at least one of the side walls of the equipment enclosure is in contact with at least one of the side walls of the inner shroud.

7. The assembly of claim 6, wherein a temperature sensor is located inside the equipment enclosure and operation of at least one of the top fan and the internal fan is controlled using measurements obtained from the temperature sensor.

8. The assembly of claim 6, wherein a temperature sensor is located outside the equipment enclosure and operation of at least one of the internal fan and the top fan is controlled using measurements obtained from the temperature sensor.

9. An assembly for cooling electronic equipment, comprising in combination:
a shroud having three side walls, an upper wall having an opening, and a front wall located along two of the side walls and the upper wall of the shroud; and
a top fan mounted on the upper wall of the shroud, wherein the top fan draws external air in an upward direction along at least one of the side walls of the shroud.

10. The assembly of claim 9, wherein the top fan draws the external air into the shroud assembly through an inlet located on a lower portion of at least one of the shroud side walls.

11. The assembly of claim 9, wherein at least one external surface of at least one of the top fan and the shroud has a reflective coating.

12. The assembly of claim 9, wherein the shroud is located around an equipment enclosure.

13. The system of claim 9, wherein at least one of the side walls and upper wall of the shroud is coated with a powder-coat paint.

14. The assembly of claim 12, wherein the equipment enclosure comprises:
electronic equipment;
at least one internal fan, wherein the internal fan directs air inside the equipment enclosure in a downward direction across at least one of the side wails of the equipment enclosure; and
at least one first channel between the electronic equipment and the side walls of the equipment enclosure;
wherein at least one second channel is located between the side walls of the shroud and the side walls of the equipment enclosure; and
wherein a seal is located between the shroud front wall and the equipment enclosure.

15. The system of claim 14, wherein a temperature sensor is located inside the equipment enclosure; and
wherein at least one of the internal fan and the top fan is a single-speed fan, and wherein the operation of the single-speed fan is controlled using measurements obtained from the temperature sensor.

16. The system of claim 14, wherein a temperature sensor is located inside the equipment enclosure; and
wherein at least one of the internal fan and the top fan is a variable-speed fan, and wherein the speed of the variable-speed fan is controlled using measurements obtained from the temperature sensor.

17. The system of claim 14, wherein a temperature sensor is located outside the equipment enclosure and operation of at least one of the top fan and the internal fan is controlled using measurements obtained from the temperature sensor.

18. A method for cooling electronic equipment, comprising:
using an first fan to direct internal air within an equipment enclosure in a downward direction across side walls of the equipment enclosure; and
using an second fan to direct external air between the equipment enclosure and a shroud assembly located around the equipment enclosure in an upward direction, wherein the external air moves from an air intake located on a lower portion of at least one side wall of the shroud assembly to an air exhaust located at a top surface of the shroud assembly; and
wherein heat exchange takes place across the side walls of the equipment enclosure.

19. The method of claim 18, providing a reflective coating on at least one surface of the shroud.

20. The method of claim 18, using an output from a temperature sensor located to control the operation of at least one of the first fan and the second fan.
